(19) United States
(12) Patent Application Publication
(10) Pub. No.: US 2005/0052291 A1
(43) Pub. Date: Mar. 10, 2005

(54) Portable data input device and use of such a device

(75) Inventors: Jonas Backman, Danderyd (SE); Kurt Hognelid, Bromma (SE); Fredrik Madsen, Stockholm (SE); Magnus Schnurer, Bromma (SE); Tomas Oquist, Upplands Vasby (SE)

Correspondence Address: McCormick Paulding & Huber, City Place II, 185 Asylum Street, Hartford, CT, 06103-3402, US

(73) Assignee: Perific AB, Sundbygerb (SE)

(21) Appl. No.: 10/493,956

(22) PCT Filed: Oct. 30, 2002
(86) PCT No.: PCT/SE02/01972

(30) Foreign Application Priority Data
Oct. 30, 2001 (SE) 0103600-3

(51) Int. Cl. H03M 11/00; H03K 17/94

(52) U.S. Cl. 341/22; 341/20

(57) ABSTRACT

The invention concerns a portable data input device. The device comprises a holding member designed to be held by or attached to a first hand of a user of the device in order to hold the device onto said first hand. The device comprises a first plurality of input members arranged on the back of the first hand and/or on the sides of the first hand, such that these input members may be easily manipulated by a plurality of fingers of the second hand of the user. The device also comprises a second plurality of input members arranged on the palm-side of the first hand, such that these input members may be easily manipulated by a plurality of fingers of the first hand. With the help of the input members of the device, essentially all the basic symbols of a standard computer keyboard can be generated. The invention also concerns the use of such a device.

### CROSS-REFERENCE TO RELATED APPLICATIONS

This application is entitled to the benefit of and incorporates by reference essential subject matter disclosed in International Patent Application No. PCT/SE02/01972 filed on Oct. 30, 2002 and Swedish Patent Application No. 0103600-3 filed on Oct. 30, 2001.

### BACKGROUND OF THE INVENTION AND PRIOR ART

The present invention relates to a portable data input device comprising:
a holding member designed to be held by or attached to a first hand of a user of the device in order to hold the device onto said first hand,
a set of input members, designed to be manipulated by fingers of the user, arranged on said holding member, wherein this set of input members includes a plurality of input members arranged on said holding member such that, when the holding member is held or attached as intended to said first hand, the plurality of input members are located on the palm-side of the first hand, such that these input members may be manipulated by a plurality of fingers of the first hand of the user.

The invention also relates to a use of such a device.

A data input device of the above kind is known from U.S. Pat. No. 4,905,001. FIG. 2-4 in this document discloses that this input device may have two input members for the index finger of the first hand: one input member is manipulated by the fingertip and the other input member is manipulated with the part of the finger located closest to the hand. The device has two similar input members for each of the middle finger, the ring finger and the little finger. With the help of these eight input members ASCII codes may be generated that represent, inter alia, the different letters of the alphabet.

This kind of input device is quite difficult to learn to use. The positions of the two input members for each finger make it difficult for a user to quickly generate the different symbols to be inputted.

GB-A-2305714 discloses a keyboard glove. The keyboard glove has input members positioned under the fingertips. With this keyboard glove it is possible to generate inputs on any surface by pressing the fingertips with the glove on such a surface. The keyboard glove may also have some function keys that are seldom used positioned on the glove on the back of the hand of the user. The different symbols to be inputted are generated by simultaneously pressing combinations of different input members. One disadvantage with this kind of input device is that it is difficult to use the hands, in particularly the fingertips, for other purposes, since the input members are positioned on the fingertips.

Of course, standard computer keyboards are also known. One disadvantage with such a keyboard is that it has to be positioned on a suitable surface in order for a user to input characters. A standard computer keyboard does therefore not allow for a particularly flexible working position. A static working position may course injuries. Furthermore, such a standard computer keyboard is relatively large and cumbersome.

### SUMMARY OF THE INVENTION

An object of the present invention is to provide a portable data input device which allows for a flexible working position. A further object is to provide such a device that is easy and comfortable to use. Another object is to provide such a device with which an efficient and fast input of different input characters is possible. A still further object is to provide such a data input device which may be worn on one hand and which allows for the fingers of that hand to be used for other purposes when not being used to input characters with the help of the device.

The above objects are obtained by a portable data input device comprising:
a holding member designed to be held by or attached to a first hand of a user of the device in order to hold the device onto said first hand,
a set of input members, designed to be manipulated by fingers of the user, arranged on said holding member, wherein this set of input members includes
   a first plurality of input members arranged on said holding member such that, when the holding member is held or attached as intended to said first hand, the first plurality of input members are located on the back of the first hand and/or on the sides of the first hand, such that these input members may be easily manipulated by a plurality of fingers of the second hand of the user, and
   a second plurality of input members arranged on said holding member such that, when the holding member is held or attached as intended to said first hand, the second plurality of input members are located on the palm-side of the first hand, such that these input members may be easily manipulated by a plurality of fingers of the first hand of the user by bending said fingers to reach said second plurality of input members,
wherein said set of input members and said device are arranged such that by manipulating said input members of said set, data signals representing essentially all the basic symbols of a standard computer keyboard can be generated.

It should be noted that by the expression “the basic symbols of a standard computer keyboard” is meant the basic letter symbols that keyboards of a certain standard type always have in common and that have predetermined positions according to this standard. For example, for an English QWERTY keyboard, all the letters of the alphabet are included in the “basic symbols”. The invention is of course applicable to implement any other kind of standardised keyboard.

By the expression “essentially all the basic symbols” is meant that at least a large majority of the basic symbols may be generated. It is possible that for example one or a few seldom-used letters cannot be generated by manipulating the input members. However, according to a preferred embodiment all said basic symbols can be generated by manipulating said input members.

It should also be noted that according to a preferred embodiment it is necessary to use input members of both said first plurality and said second plurality in order to generate all said basic symbols.

It can also be mentioned that according to a preferred embodiment, the holding member constitutes one single integral unit onto which said first and second plurality of input embers are arranged. However, according to an alternative embodiment, the holding member may comprise two different parts: one part on which the first plurality of input members are arranged and one part on which the second plurality of input members are arranged. Such two parts may be connected together before the holding member is positioned onto a hand of a user. Alternatively, such two parts may be positioned separately on the back of the hand and on the palm side of the hand, respectively.

Also according to a preferred embodiment, the holding member is designed such that the device is held onto said hand without there being any need for the user to grip the device. The holding member is thus designed to securely hold the device onto the hand. However, alternatively, it is possible that the holding member is designed such that it does not by itself hold the device securely fastened to the hand, but such that the user may need to hold the holding member by the use of one or more fingers in order to maintain the device onto the hand.

It may also be mentioned that by “a plurality of input members” is meant at least two input members.

Since the input device has both the first and the second plurality of input members, both hands can be used when inputting data. Therefore, data may be inputted in a fast manner. Furthermore, since the second plurality of input members are not positioned on the finger tips themselves, but on the palm-side of the first hand, the fingers, or at least the finger tips, may be used for other purposes when the fingers are not being bent to reach the second plurality of input members. It has also been found to be a very comfortable working position to have a plurality of input members positioned as said first plurality. The second hand may, for example, rest against the first hand when using the fingers of the second hand to manipulate said first plurality of input members. The device also allows for a flexible working position. For example, when using the device, the hands may rest in the lap of the person using the device or on a desk or on another surface. Alternatively, it is also possible to hold the hands in front of the user while using the device. It is of course possible to stand up, sit down or even lie down when using the device.

According to a preferred embodiment of the device, the device and the input members are arranged such that those of said basic symbols of a standard computer keyboard that are normally generated with the fingers of the second hand on said standard keyboard, can be generated by manipulating said first plurality of input members, alone or together with some special function input member.

According to a further embodiment, the device and the input members are arranged such that those of said basic symbols of a standard computer keyboard that are normally generated with the fingers of the first hand on said standard keyboard, can be generated by manipulating said second plurality of input members, alone or together with some special function input member. It has been found that it is easier to learn to use the device, if the device is set up or programmed such that the same hand is used for generating certain input symbols as would be used on a standard computer keyboard.

According to a further embodiment, said first plurality of input members comprises at least one input member for each of the four fingers of the second hand including the index finger, the middle finger, the ring finger and the little finger. By having at least one input member for each of said four fingers of the second hand, data may be inputted in an efficient and quick manner.

According to another embodiment, said second plurality of input members comprises at least one input member for each of the four fingers of the first hand including the index finger, the middle finger, the ring finger and the little finger. By also having at least one input member for each of the four fingers of the first hand, input symbols may be generated even more efficiently.

According to a still further embodiment, the input members of said set of input members are arranged at such positions and the device is arranged such that each of said basic symbols of a standard computer keyboard is intended to be generated by manipulation of an input member, alone or together with some special function input member, with the same finger as would normally be used when the symbol is generated on the standard keyboard. By arranging input members in this manner, it is easy for a user, accustomed to a standard computer keyboard, to learn to use the data input device of the present invention.

According to another embodiment, the device is arranged such that the positions of at least some of the input members of said set are adjustable. The device may thereby be adapted to be suitable for different users. Furthermore, since the positions of the input members may be varied, a user may to some extent vary the positions of the fingers. This is also advantageous from an ergonomic point of view.

According to a further embodiment, said second plurality of input members comprises at least four input members, the positions of which are adjustable such that the position of these input members can be adjusted to be closer to or further away from the fingertips of the four fingers of the first hand including the index finger, the middle finger, the ring finger and the little finger when these fingers are held only slightly bent. The positions of these at least four input members may for example be moved closer to the finger tips when the input device is used and moved further away form the finger tips when the input device is not used. By being able to retract the input members when not using the device, the fingers of said first hand are even more free to be used for other purposes.

According to still another embodiment, said first plurality of input members comprises at least four input members arranged to be manipulated by four fingers of the second hand including the index finger, the middle finger, the ring finger and the little finger, wherein the positions of said at least four input members are adjustable such that they can be lined up more across the back of said first hand or more along the length of the back of said first hand. The position of the second hand relative to the first hand may thereby be varied. A user may thus choose a position of the second hand relative to the first hand which is found comfortable for the particular user.

According to a further embodiment, the device comprises a transmitter unit arranged for transmitting said data signals in a wireless manner to a peripheral unit that does not form part of the data input device. The peripheral unit may for example constitute a computer. The data input device may thus communicate with the computer in a wireless manner. However, within the scope of the invention is of course also the possibility that the data input device is connected to a peripheral unit via a cable.

According to a further embodiment, the holding member comprises a U-shaped portion, which thus has first and second at least relatively straight parts and a bent part connecting said first and second parts, wherein said device is designed to be attachable to said first hand such that the first part is located essentially on the back of the hand, the second part is located essentially on the front of the hand while the bent part extends from the back of the hand to the front of the hand in the region between the thumb and the index finger of said first hand. With such a U-shaped portion it is easy to attach the device to the hand of a user. Furthermore, with the help of such a U-shaped portion the device is securely attached to the hand.

According to another embodiment, at least one input member of said set of input members is arranged for inputting signals in order to perform the same or a similar function as a joystick or as the movement of a standard computer mouse. It is advantageous if the input device comprises such an input member, since such a pointer arrangement is often advantageous to use when, for example, operating a computer.

According to a further embodiment, said set of input members includes one or more input members arranged for inputting signals in order to fulfil the function of special function keys such as Alt, Ctrl, Shift or the like. With the help of such special function keys, further input symbols or other commands may be generated.

According to a further embodiment, said first plurality of input members comprises at least four input members arranged to be manipulated by four fingers of the second hand including the index finger, the middle finger, the ring finger and the little finger, and wherein at least one of said special function keys is positioned such that it may be easily manipulated by the thumb of said second hand, while the remaining fingers of said second hand may manipulate said at least four input members. Such a position of the special function keys makes it easy to use such keys.

According to a still further embodiment, at least one of said special function keys is positioned such that it is easily manipulated by the thumb of said first hand. Thereby also the thumb of the first hand may be used for input purposes.

According to a further embodiment, the holding member includes at least a portion designed to correspond to the shape of a predetermined portion of a normal hand of a user. The holding member is thus particularly adapted to the shape of a hand. The device can therefore be securely attached to the hand and is also comfortable to wear.

According to a further embodiment, the holding member or a portion thereof is designed such that the shape of the holding member or said portion may be varied to fit onto different hands or onto different positions of the hand. This allows for larger flexibility in the use of the device.

Another aspect of the invention concerns a use of the portable data input device according to any of the above embodiments, wherein said holding member is attached to said first hand such that said first and second plurality of input members are positioned as defined in claim 1. Such a use of the device has the advantages discussed above in connection with the device itself.

According to a further manner of using the device, said first plurality of input members are so positioned and said hands are held for manipulating the input members by arranging the four fingertips of the index finger, the middle finger, the ring finger and the little finger of the second hand such that these fingertips may rest on respective input members and such that these fingertips are essentially lined up across the back of said first hand. The palm of the second hand may thereby rest against the fingers of the first hand. This has been found to be a comfortable manner of using the device.

According to a further manner of using the device, said first plurality of input members are so positioned and said hands are held for manipulating the input members by arranging the four fingertips of the index finger, the middle finger, the ring finger and the little finger of the second hand such that these fingertips may rest on respective input members and such that these fingertips are essentially lined up on the back of the first hand essentially in the longitudinal direction of the hand. The second hand may thereby approach the first hand from the side. Also this has been found to be a comfortable manner of using the device. Of course, it is also possible that the input members are arranged such that the mentioned fingertips are lined up at an angle between the two mentioned manners.

### SHORT DESCRIPTION OF THE DRAWINGS

FIG. 1 shows schematically a portable data input device according to the invention attached to a hand of a user.

FIG. 2 shows schematically a cross-section of the data input device and the hand according to the section marked A-A in FIG. 1.

FIG. 3 shows schematically a similar view as FIG. 1 of another embodiment of the data input device.

FIG. 4 shows schematically a U-shaped portion of the data input device and the hand in a similar section as is shown in FIG. 2.

FIG. 5 shows schematically a similar view as FIG. 1 of another embodiment of the invention.

FIG. 6 shows schematically a side view of a hand with an attached data input device according to a further embodiment of the invention.

### DESCRIPTION OF PREFERRED EMBODIMENTS

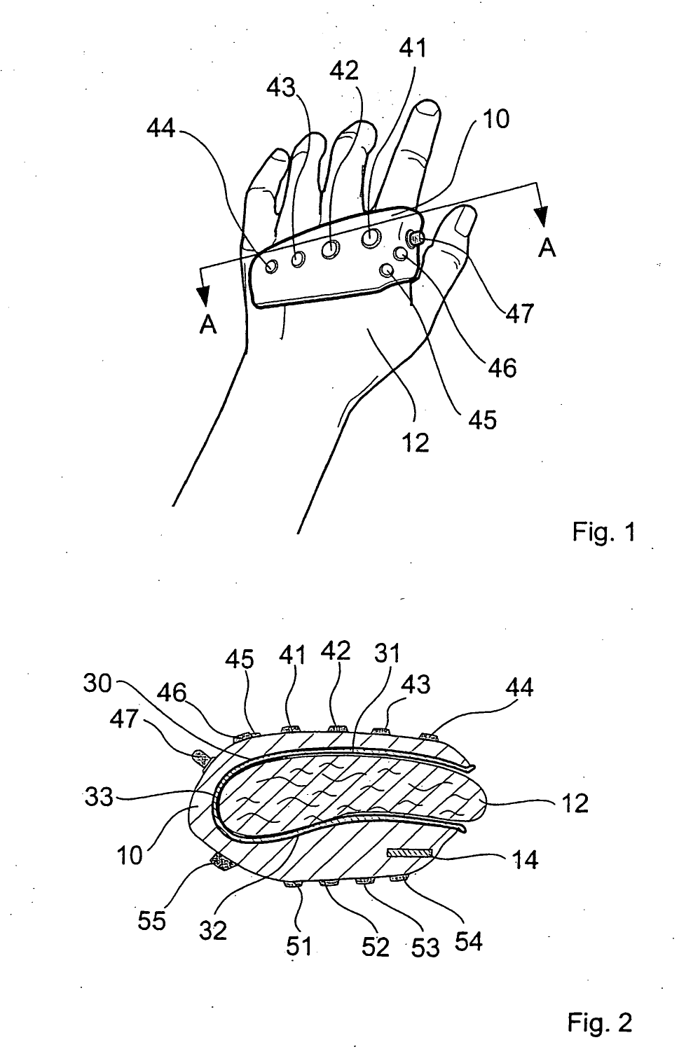

An embodiment of the invention will now first be described with reference to FIG. 1 and FIG. 2. It should be noted that in FIG. 2 (and in FIG. 4) the thumb of the hand is not shown.

FIGS. 1 and 2 thus show a data input device according to the invention attached to a first hand 12 of a user of the device. In this case the first hand 12 is the left hand. The device according to the invention could however equally well be designed to be worn on the right hand. The data input device comprises a holding member 10 on which input members 41-55 are arranged. The holding member 10 has the function to hold the device onto a hand 12 and also to hold the input members 41-55, which are arranged on the holding member 10, at certain positions relative to the hand 12.

In the shown embodiment, the holding member 10 includes a U-shaped portion 30 (see also FIG. 4). The U-shaped portion 30 has first 31 and second 32 relatively straight parts and a bent part 33 connecting the first 31 and second 32 parts. As can be seen in FIG. 2, when the device is attached to the hand 12, the first part 31 is located essentially on the back of the hand 12. The second part 32 is located essentially on the front of the hand 12. The bent part 33 extends from the back of the hand 12 to the front of the hand 12 in the region between the thumb and the index finger of the hand 12. As is shown in FIG. 4, the holding member 10 may include a locking member 36 to securely lock the holding member 10 or the U-shaped portion 30 to the hand 12. It should be noted that for the sake of simplicity FIG. 4 only shows the U-shaped portion 30 and a locking member 36, but not the remaining part of the holding member 10. It should also be noted that although the U-shaped portion 30 in FIG. 2 is shown with a different hatching that the rest of the holding member 10, the U-shaped portion 30 may constitute one integral portion of the holding member 10, i. e. the U-shaped portion may be considered to constitute that portion of the holding member which is closest to the hand 12.

The portion 30 that is in direct contact with the hand 12 may be designed to have a shape corresponding to the shape of the corresponding portion of the hand 12. The holding member 10 may be designed such that it may fit onto hands of different shapes and sizes. For example, the holding member 10, or at least a portion 30 thereof, may be made of a flexible material or may be provided with adjustment means by means of which it is possible to adjust the size of the holding member 10 to the size of the hand. The holding member 10 may also be supplied with some kind of inlays of different sizes with the help of which the size of the device may be adapted to a particular hand. The holding member 10 may also be made of a material that can be adapted to the shape of the hand, for example by heating the holding member 10. The holding member 10 may also be provided with different kinds of spring-like members to securely hold the device onto the hand. The holding member 10 may also be provided with different kinds of attachable pads of a softer material on the inside of the holding member 10. With the help of such pads the shape of the holding member 10 may be adjusted to a particular hand. Such a padding could be formed by any suitable flexible material, such as a foam material or by gel or air-filled pads.

It should be noted that to design the holding member 10 such that its includes a U-shaped portion 30 is only one possible design for holding the device onto the hand 12. The holding member 10 or the holding portion 30 could have different designs. It is for example possible that the holding member 10 is shaped as a glove which is worn on the hand. The data input device could also be held to the hand with the help of different kinds of bands or straps, for example held to the hand with velcro-bands. According to an alternative embodiment (not shown), the holding member 10 is designed such that it does not by itself hold the device onto the hand 12. Instead the user needs to hold the holding member 10 onto the hand 12 by using one or more fingers.

The portion of the holding member 10 that is in contact with the hand 12 is, according to a preferred embodiment, formed of a material or with a texture that allows air to reach the portion of the hand located below the holding member 10. It should also be noted that if a U-shaped portion 30 is used, it would also be possible that the mentioned part 33 is located on the outside of the hand instead of in the area between the thumb and the index finger.

To return to FIG. 1 and FIG. 2, the device comprises a set of input members 41-55 designed to be manipulated by fingers of the user who is wearing the input device on the hand 12. The set of input members 41-55 includes a first plurality of input members 41-44. These input members 41-44 are arranged on the holding member 10 such that when the holding member is attached to the hand 12, the input members 41-44 are located on the back of the hand 12. Alternatively, some of the input members 41-44 could be positioned on the sides of the hand 12. The position of these input members 41-44 is such that these input members may be easily manipulated by a plurality of fingers of the other hand of the user.

The device also comprises a second plurality of input embers 51-54. These input members 51-54 are arranged such that when the holding member 10 is attached to the hand 12, these input members 51-54 are located on the palm-side of the hand 12. These input members 51-54 are positioned such that they are easily manipulated by a plurality of fingers of the hand 12 by bending the fingers to reach the input members 51-54.

In addition to the first 41-44 and second 51-54 pluralities of input members, the device may comprise other input members 45, 46, 47, 55. The input members 41-55 and the device are arranged or programmed such that by manipulating the input members 41-55, data signals representing preferably all (but at least essentially all) the basic symbols of a standard computer keyboard can be generated. The expression “basic symbols” has been explained above. The idea behind the invention is thus that all these basic symbols of a standard keyboard may be generated by manipulating suitable input members 41-55 of the device, while the device is attached to a hand 12 of the user.

Preferably, the device is arranged such that those of the basic symbols of a standard computer keyboard normally generated with the fingers of the second hand (in this case the right hand) may be generated by manipulating the first plurality of input members 41-44, alone or together with some special function input member 45, 46, 55. Similarly, preferably the basic symbols of a standard computer keyboard that are normally generated with the fingers of the first hand 12 (in this case the left hand) may preferably be generated by manipulating the second plurality of input members 51-54, alone or together with some special function input member 45, 46, 55.

The number of input members 41-55 may vary. However, according to a preferred embodiment, there is at least one input member 41-44 for each of the index finger, the middle finger, the ring finger and the little finger of the second hand. Similarly, preferably there are at least one input member 51-54 for each of the index finger, the middle finger, the ring finger, and the little finger of the first hand 12.

Preferably, the input members 41-55 and the device are arranged such that each of the basic symbols of a standard computer keyboard may be generated by manipulation of an input member, alone or together with some special function input member 45, 46, 55, with the same finger as would normally be used when the symbol is generated on the standard keyboard. For example, on a standard QWERTY keyboard, the index finger of the right hand is, according to a normal standard finger setting, used to press the basic keys for the letters U, J, M, Y, H and N. If the device according to the invention emulates a standard QWERTY keyboard, the input members are thus positioned such that at least one input member 41 may be easily manipulated by the index finger of the right hand and such that by manipulating this at least one input member 41, possibly together with some special function input member 45, 46, 55, all these letters U, J, M, Y, H and N may be generated. This can be achieved in different manners. One possibility is of course that there are six input embers dedicated to the index finger of the right hand.

Another possibility is that there are two input members dedicated to the index finger of the right hand. One of these input members could for example be used to generate the symbols Y, H and N and one input member could be used for generating the symbols U, J and M. This function of the two input members may be obtained in different manners. One manner is that the different letters are generated by pressing the input member in question one, two or three times in a similar manner as is often the case in a cellular telephone. Another possibility is that one or more special input member 45, 46, 55 is used to decide, for example, whether the pressing of the input member with the index finger means Y, H or N. According to one possible embodiment, the device may include six input members dedicated to the four fingers (excluding the thumb) of each hand: two input members for the index finger, two input members for the little finger and one input member for each of the middle finger and the ring finger. This embodiment may, for example, be combined with the feature that each input member may generate different states as explained below.

Another possibility is to use only one input member 41 for the index finger of the right hand. According to this possibility, the different symbols may be generated by special keys 45, 46, 55. For example, one key may mean a shift to the left (in this example from J to H) while another shift function may be the selection of the row on the keyboard (i. e. from H to Y or N and from J to U or M). It should be mentioned that the different shift possibilities according to the above described example, could also be obtained by a special key 45, 46, 55 by designing this key in a similar manner as the +-key which is sometimes used on input units for computer games. Such a key could be designed to generate 8 different states: in addition to the left, right, up and down states of the +-key, also “up and to the left”, “up and to the right”, “down and to the left” and “down and to the right”. With such a key an input member could be shifted to the left, to the right and up and down corresponding to the different symbols on a standard computer keyboard.

Still another possibility is that each input member 41-44 may be used to generate different states. For example, an input member could be designed such that one state is generated by pressing one half of the input member, another state by pressing the other half of the input member and a third state by pressing the middle of the input member. For example: by pressing the upper half of a certain key, U is generated, by pressing the lower half of the key, M is generated and by pressing the middle of the key, J is generated.

It should be mentioned that although the above examples have only dealt with the key for the index finger of the right hand, a similar consideration can be made for the little finger of the right hand. Also this finger usually covers at least six positions on a standard computer keyboard. The same consideration could of course be made for the different input members 51-54 designed to be pressed by the fingers of the left hand in the above example.

It is also possible to arrange the device such that it is anticipated which words are to be inputted based on a dictionary and statistics of the use of different words in a language or by a user. Such algorithms are known, for example, in connection with cellular telephones. One example of such an algorithm is the so-called T9 algorithm. Different input symbols which do not constitute part of the normal basic symbols of a standard computer keyboard may be generated by different shift buttons or by combinations of keys.

The device according to the invention preferably comprises at least one input member 47 which is arranged to fulfil the same function as a joystick or as the movement of a standard computer mouse, i. e. the input member 47 constitutes a pointer device. The input member 47 may be formed as a small joystick, but alternatively any other kind of pointer device can be used, for example in the form of a touch pad, a ball, an optical sensor which senses the movement of a finger etc.

In order to allow for a flexible and adjustable working position, one or more input members 41-55 may be arranged movably such that the position of the input member or members may be adjusted. The input members 41-55 may be arranged such that they are individually adjustable. Another possibility is that the position of a group of input members may be adjusted together. For example, the mentioned second plurality of input members 51-54 may be arranged such that the position of these input members 51-54 may be adjusted to be closer to or further away from the finger tips of the four fingers of the first hand 12 which are intended to be used to manipulate these input members 51-54. This may for example be implemented as shown schematically in FIG. 6. The input members 51-54 are here positioned on a movable supporting portion 60. The position of this portion 60 may be varied by rotating the portion 60 around an axis of rotation 62. The device preferably comprises means which makes it possible to lock the portion 60 in a suitable position.

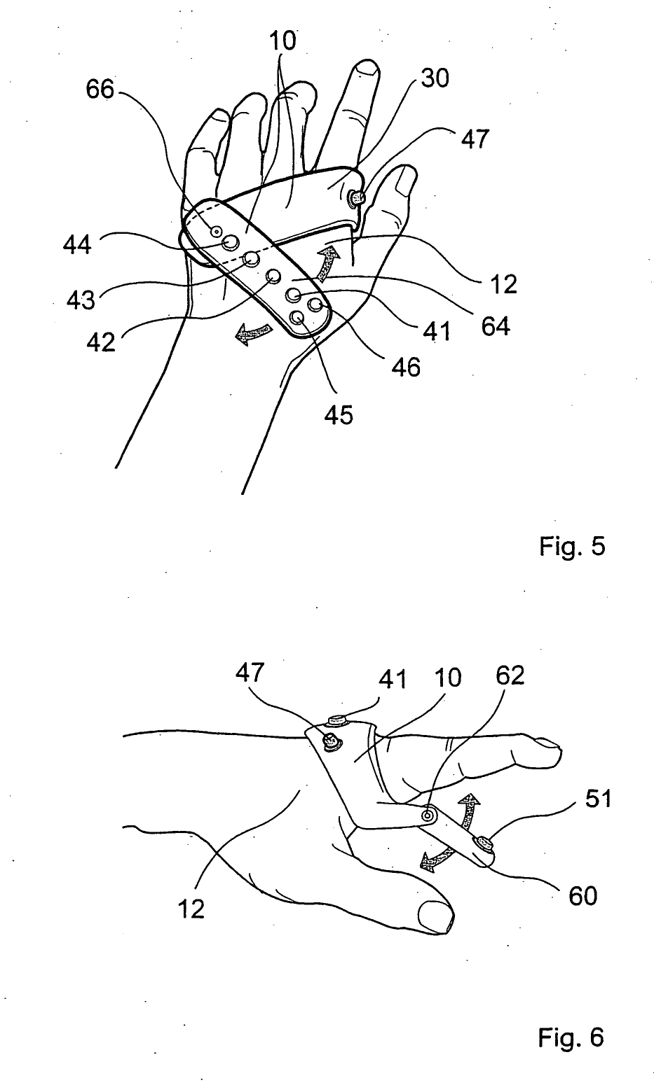

FIG. 5 shows an example where the position of the input members 41-46 may be adjusted. According to this example, the input embers 41-46 are positioned on a portion 64 which is movable relative to a U-shaped holding portion 30. The movement may be made possible by rotation around an axis 66. The device also preferably includes means for locking the portion 64 in the chosen position.

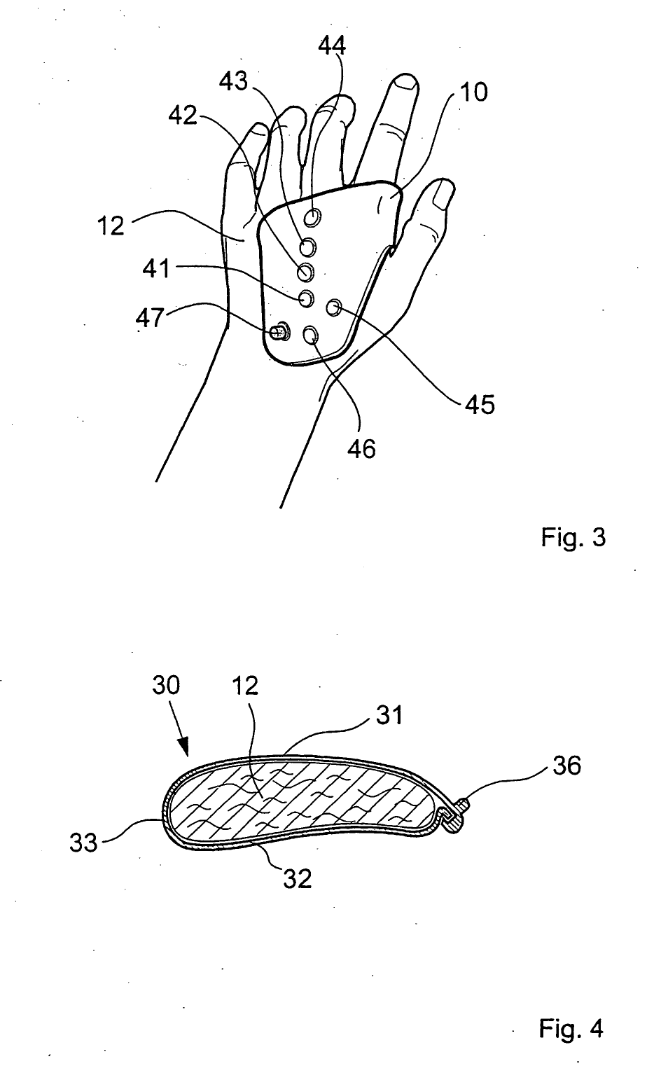

FIG. 3 shows an embodiment where the input members 41-44 are arranged such that they a lined up more along the length of the back of the hand 12.

Preferably, the data input device comprises a transmitter unit 14 which is arranged for transmitting data signals in a wireless manner to a peripheral unit that does not form part of the input device. The peripheral unit may constitute for example a computer to which signals are inputted with the help of the data input device.

It should be noted that the data input device according to the invention normally also comprises necessary electronics for generating the different inputs. The data input device may include a battery and also a memory such that inputted data may be stored in the memory and then transferred to a peripheral device later. It is of course also possible that the data input device according to the invention comprises some kind of display for directly showing the symbols that are inputted. Preferably, some of the special function keys 45, 46, 47, 55 are positioned such that at least some of them are easily manipulated by the thumb of the second hand (in this case the right hand) while the remaining fingers of the second hand may manipulate the first plurality of input members 41-44. In the embodiment shown in FIG. 1, the input members 45, 46 and 47 may be manipulated by the thumb of the right hand.

Preferably, the data input device comprises at least one input member 55 arranged to be operated by the thumb of the first hand 12.

The data input device according to the invention is preferably used by arranging the device onto the hand in the manner shown in the Figures. According to one manner of using the device, the fingertips of the second hand are lined up across the back of the first hand 12. With reference to FIG. 1, this can be done in that the index finger of the right hand is arranged on the input member 41, the middle finger of the right hand is positioned on the input member 42, the ring finger of the right hand is positioned on the input member 43 and the little finger of the right hand is positioned on the input member 44.

The fingertips of the second hand may according to an alternative manner of using the device be positioned more in the longitudinal direction of the hand. This may be done with the help of the arrangement shown in FIG. 3 in that the respective index, middle, ring and little fingers of the right hand are positioned on the respective input members 41-44. Alternatively, the positions of the input members 41-44 shown in FIG. 3 could be reversed and the input members could be manipulated by holding the right hand below and around the left hand in order to reach the input members 41-44.

It is also possible that the input members 41-44 are lined up such that the input member 41 is located more to the left of the hand (as seen in FIG. 3) than the other input members 42-44. When using such a device, the angle between the arms of the user tends to be less than 90°.

The invention is not limited to the described embodiments but may be varied and modified within the scope of the following claims.

1-20. (Canceled)

21. A portable data input device comprising:
a holding member designed to be held by or attached to a first hand of a user of the device in order to hold the device onto said first hand,
a set of input members, designed to be manipulated by fingers of the user, arranged on said holding member, wherein this set of input members includes
a first plurality of input members arranged on said holding member such that, when the holding member is held or attached as intended to said first hand, the first plurality of input members are located on the back of the first hand and/or on the sides of the first hand, such that these input members may be easily manipulated by a plurality of fingers of the second hand of the user, and
a second plurality of input members arranged on said holding member such that, when the holding member is held or attached as intended to said first hand, the second plurality of input members are located on the palm-side of the first hand, such that these input members may be easily manipulated by a plurality of fingers of the first hand of the user by bending said fingers to reach said second plurality of input members,
wherein said set of input members and said device are arranged such that by manipulating said input members of said set, data signals representing essentially all the basic symbols of a standard computer keyboard can be generated.

22. A portable data input device according to claim 21, wherein the device and the input members are arranged such that those of said basic symbols of a standard computer keyboard that are normally generated with the fingers of the second hand on said standard keyboard, can be generated by manipulating said first plurality of input members, alone or together with some special function input member.

23. A portable data input device according to claim 22, wherein the device and the input members are arranged such that those of said basic symbols of a standard computer keyboard that are normally generated with the fingers of the first hand on said standard keyboard, can be generated by manipulating said second plurality of input members, alone or together with some special function input member.

24. A portable data input device according to claim 21, wherein said first plurality of input members comprises at least one input member for each of the four fingers of the second hand including the index finger, the middle finger, the ring finger and the little finger.

25. A portable data input device according to claim 21, wherein said second plurality of input members comprises at least one input member for each of the four fingers of the first hand including the index finger, the middle finger, the ring finger and the little finger.

26. A portable data input device according to claim 21, wherein the input members of said set of input members are arranged at such positions and the device is arranged such that each of said basic symbols of a standard computer keyboard is intended to be generated by manipulation of an input member, alone or together with some special function input member, with the same finger as would normally be used when the symbol is generated on the standard keyboard.

27. A portable data input device according to claim 21, wherein the device is arranged such that the positions of at least some of the input members of said set are adjustable.

28. A portable data input device according to claim 27, wherein said second plurality of input members comprises at least four input members, the positions of which are adjustable such that the position of these input members can be adjusted to be doser to or further away from the fingertips of the four fingers of the first hand including the index finger, the middle finger, the ring finger and the little finger when these fingers are held only slightly bent.

29. A portable data input device according to claim 27, wherein said first plurality of input members comprises at least four input members arranged to be manipulated by four fingers of the second hand including the index finger, the middle finger, the ring finger and the little finger, wherein the positions of said at least four input members are adjustable such that they can be lined up more across the back of said first hand or more along the length of the back of said first hand.

30. A portable data input device according to claim 21, comprising a transmitter unit arranged for transmitting said data signals in a wireless manner to a peripheral unit that does not form part of the data input device.

31. A portable data input device according to claim 21, wherein the holding member comprises a U-shaped portion, which thus has first and second at least relatively straight parts and a bent part connecting said first and second parts, wherein said device is designed to be attachable to said first hand such that the first part is located essentially on the back of the hand, the second part is located essentially on the front of the hand while the bent part extends from the back of the hand to the front of the hand in the region between the thumb and the index finger of said first hand.

32. A portable data input device according to claim 21, wherein at least one input member of said set of input members is arranged for inputting signals in order to perform the same or a similar function as a joystick or as the movement of a standard computer mouse.

33. A portable data input device according to claim 21, wherein said set of input members includes one or more input members arranged for inputting signals in order to fulfil the function of special function keys such as Alt, Ctrl, Shift or the like.

34. A portable data input device according to claim 33, wherein said first plurality of input members comprises at least four input members arranged to be manipulated by four fingers of the second hand including the index finger, the middle finger, the ring finger and the little finger, and wherein at least one of said special function keys is positioned such that it may be easily manipulated by the thumb of said second hand, while the remaining fingers of said second hand may manipulate said at least four input members.

35. A portable data input device according to claim 33, wherein at least one of said special function keys is positioned such that it is easily manipulated by the thumb of said first hand.

36. A portable data input device according to claim 21, wherein the holding member includes at least a portion designed to correspond to the shape of a predetermined portion of a normal hand of a user.

37. A portable data input device according to claim 21, wherein the holding member or a portion thereof is designed such that the shape of the holding member or of said portion may be varied to fit onto different hands or onto different positions of the hand.

38. Use of a portable data input device according to claim 21, wherein said holding member is attached to said first hand.

39. Use according to claim 38, wherein said first plurality of input members are so positioned and said hands are held for manipulating the input members by arranging the four fingertips of the index finger, the middle finger, the ring finger and the little finger of the second hand such that these fingertips may rest on respective input members and such that these fingertips are essentially lined up across the back of said first hand.

40. Use according to claim 38, wherein said first plurality of input members are so positioned and said hands are held for manipulating the input members by arranging the four fingertips of the index finger, the middle finger, the ring finger and the little finger of the second hand such that these fingertips may rest on respective input members and such that these fingertips are essentially lined up on the back of the first hand essentially in the longitudinal direction of the hand.
